(19) United States
(12) Patent Application Publication
(10) Pub. No.: US 2012/0216870 A1
(43) Pub. Date: Aug. 30, 2012

(54) INTERLAYER FOR ORGANIC SOLAR CELLS

(75) Inventors: Franky So, Gainesville, FL (US); Jegadesan Subbiah, Gainesville, FL (US); John R. Reynolds, Dunwoody, GA (US); Chad Martin Amb, Midland, MI (US); Pierre Marc Beaujuge, Jeddah (SA)

(73) Assignee: UNIVERSITY OF FLORIDA RESEARCH FOUNDATION INC., GAINESVILLE, FL (US)

(21) Appl. No.: 13/505,562

(22) PCT Filed: Nov. 2, 2010
(86) PCT No.: PCT/US10/55076

§ 371 Date: May 2, 2012

Related U.S. Application Data
(60) Provisional application No. 61/257,524, filed on Nov. 3, 2009.
(60) Provisional application No. 61/265,500, filed on Dec. 1, 2009.

(51) Int. Cl. H01L 51/46

(52) U.S. Cl. 136/263

(57) ABSTRACT

An organic PV solar cell that has an anode double interlayer situated between an electrode and an organic photoactive layer displays superior power conversion efficiency over that of equivalent devices with an anode single interlayer. The anode double layer can comprise a hole extraction layer adjacent to the anode and an organic hole accepting electron blocking material layer that comprises an aromatic amine compound with a plurality of N atoms. The hole extraction layer can be a metal oxide or an n-type organic semiconductor.

### CROSS-REFERENCE TO RELATED APPLICATIONS

The present application claims the benefit of U.S. Provisional Application Ser. No. 61/257,524, filed Nov. 3, 2009, and U.S. Provisional Application Ser. No. 61/265,500, filed Dec. 1, 2009, the disclosures of which are hereby incorporated by reference in their entireties, including any figures, tables, or drawings.

### BACKGROUND OF INVENTION

Organic photovoltaic (OPV) cells are increasingly investigated as an alternative to Si solar cells. OPV cell generally fall into three categories: dye-sensitized cells; polymer cells; and small-molecule cells. In particular, polymer cells have the potential to be low-cost, light-weight, mechanical flexibility, and permit use of high throughput manufacturing techniques. For commercial viability, power conversion efficiencies (PCEs) must be improved for polymer cells. Presently, high PCE polymer solar cells comprise an active layer where a polymer, such as a regio-regular poly(3-hexylthiophene) (P3HT), is combined with a fullerene derivative, such as [6,6]-phenyl-C₆₁ butyric acid methyl ester (PCBM), to form a phase-separated bulk-heterojunction (BHJ) having a large interfacial area for excitors dissociation. The photo-excited polymer functions as an electron donor to transporter holes to the cell's anode and the fullerene derivative functions as an electron acceptor to transport electrons to the cell's cathode. Such BHJ designs are believed to possess a number of limitations generally detrimental to this type of solar cells.

It is commonly held that the magnitude of open-circuit voltage (V_{oc}) is primarily limited by the energy difference between the highest occupied molecular orbital (HOMO) of the BHJ donor material and the lowest unoccupied molecular orbital (LUMO) of the acceptor material. Although this difference defines the theoretical maximum V_{oc}, output is typically 300 to 500 mV below this value in actual devices. Schottky barriers formed at the interfaces are believed to be a source of this deviation from optimal behavior. In reducing Schottky barriers, it is desirable to understand and control interfacial dipoles, which can be modified by carefully selecting the material mediating the interface. In addition, the use of an effective electron-blocking layer (EBL)/hole-transporting layer (HTL) may further prevent current leakage and enhance the device's output. Enhancement of the BHJ anode interface is often performed by deposition of a thin semiconducting poly(3,4-ethylenedioxythiophene):poly(styrenesulfonate) (PEDOT:PSS) layer onto the anode prior to deposition of the active layer. Although power efficiencies have been improved in this manner, more suitable materials have been sought for optimum OPV performance.

An alternative to PEDOT:PSS has been the deposition of a thin metal oxide layers, for example, NiO and MoO₃ layers, on top of an indium-tin-oxide (ITO) anode, and have been demonstrated to improve hole transport from the active polymer layer to the anode. These metal oxide layers appear to be more effective as a hole extraction layer and deficient as effective EBLs. Hence a design that maintains or improves the HTL character and significantly improves the EBL character is desirable.

### BRIEF SUMMARY

Embodiments of the invention are directed to organic photovoltaic (PV) cells that include an anode having a double interlayer coupling a transparent electrode to a photoactive layer. The double interlayer comprises a hole extracting layer and an organic hole transporting electron blocking material layer. In some embodiments of the invention, the hole extracting layer comprises a semiconducting metal oxide layer such as MoO₃, V₂O₅, WO₃, or an n-type metal oxide semiconductor. In other embodiments of the invention, the hole extracting layer comprises an n-type organic semiconductor. In some embodiments of the invention an n-type organic semiconducting material functioning as a hole extracting/injecting interlayer positioned between an electrode and a hole transport layer, where the organic material used for the hole extracting/injecting layer has a HOMO energy level that resides between the work function of the electrode and the HOMO energy level of the hole transporting layer material that facilitates hole injection.

In some embodiments of the invention, the organic hole accepting electron blocking material layer comprises an aromatic amine compound having a plurality of nitrogen atoms and can be an aromatic amine resin. Aromatic amine compound that can be used include 4,4′-bis[N-(p-tolyl)-N-phenyl-amino]biphenyl (TPD), 4,4′-bis[N-(1-naphthyl)-N-phenyl-amino]biphenyl (α-NPD), (4,4′-[bis-{(4-di-n-hexylamino)benzylideneamino)]stilbene (DHABS), 4,4′-[bis-{(4-diphenylamino)benzylideneamino}]stilbene) (DPABS), or combinations thereof. In some embodiments of the invention, the organic hole accepting electron blocking material layer comprises poly(9,9-dioctylfluorene-co-N-[4-(3-methylpropyl)]-diphenylamine) (TFB) or poly-N,N′-bis(4-butylphenyl)-N,N′-bis(phenyl)benzidine (poly-TPD).

In some embodiments of the invention the transparent anode can be ITO glass. In an embodiment of the invention the hole extracting layer comprises MoO₃ and the organic hole acceptor comprises 1,4,5,8,9,12-hexaazatriphenylene-2,3,6,7,10,11-hexanitrile [HAT(CN)₆].

### BRIEF DESCRIPTION OF DRAWINGS

FIG. 1 shows chemical structures used for various components of organic PV cells according to embodiments of the invention.

FIG. 2 shows examples of organic compounds with n-type semiconductor properties for use in devices according to embodiments of the subject invention.

FIG. 3 shows a schematic diagram of a PV device having an anode double interlayer according to an embodiment of the invention.

FIG. 4 shows a schematic diagram showing energy level of anode (ITO), anode interlayers or layer (MoO₃ and TFB, according to embodiments of the invention or PEDOT:PSS), active layer (MDMO-PPV or PSBTBT with PCBM), and cathode (Al) components according to embodiments of the invention where the electronic structure was obtained from ultra-violet photoemission spectroscopy.

FIG. 5 shows J-V curves of a MDMO-PPV/PCBM based BHJ solar cell having various anodes/anode interlayer combinations: ITO/; ITO/PEDOT:PSS; ITO/MoO₃; and ITO/MoO₃/TFB at 1.5 solar illumination, 100 mW cm⁻² for PV devices of the structure ITO/interlayer/MDMO-PPV:PCBM(1:4)/LiF/Al for comparison with the ITO/MoO₃/TFB anode double interlayer according to an embodiment of the invention.

FIG. 6 shows the external quantum efficiency of the MDMO-PPV:PCBM device with a single interlayer MoO₃ and a double interlayer MoO₃+TFB according to an embodiment of the invention.

FIG. 7 shows J-V curves for a PSBTBT:PC₇₀BM solar cell with an anode interlayer comprising PEDOT:PSS (•) and a double MoO₃/TFB (▴) according to an embodiment of the invention using 1.5 solar illumination, 100 mW cm⁻², for a device structure of ITO/anode interlayer/PSBTBT: PC_{7O}BM (1:1.5)/LiF/Al.

### DETAILED DISCLOSURE

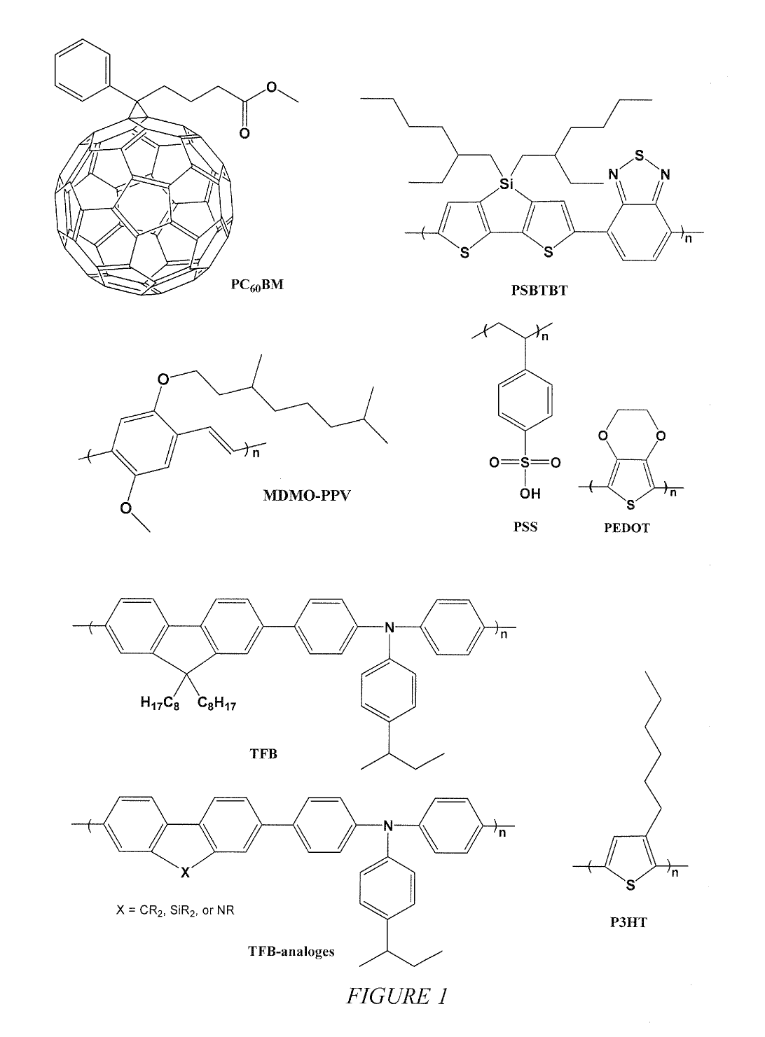

Embodiments of the invention are directed to organic PV cells that employ an anode double interlayer to act as a (EBL)/(HTL) interface between the active layer and the anode. The anode double layer comprises a semiconducting metal oxide layer for hole extracting and an organic hole transporting electron blocking material layer. In one illustrative embodiment of the invention, a double interlayer comprising MoO₃ and poly(9,9-dioctylfluorene-co-N-[4-(3-methylpropyl)]-diphenylamine) (TFB), (see FIG. 1 for its structure) is used as hole extraction and electron blocking layers at an anode to improve the fill factor (FF), short-circuit current (J_{sc}), open-circuit voltage (V_{oc}), and power conversion efficiency (PCE) of the organic PV cell. The term fill factor (FF), as used herein, refers to the ratio of the maximum power (Vₘₚ×Jₘₚ) divided by the short-circuit current density (J_{sc}) and open-circuit voltage (V_{oc}) in light current density-voltage (J-V) characteristics of solar cells. The term short circuit current density (J_{sc}), as used herein, is the maximum current through the load under short-circuit conditions. The term open circuit voltage (V_{oc}), as used herein, is the maximum voltage obtainable at the load under open-circuit conditions. The term power conversion efficiency (PCE), as used herein, is the ratio of the electrical power output to the light power input (Pᵢₙ) defined as PCE=V_{oc}J_{sc}FFPᵢₙ⁻¹ which is frequently reported as a percentage.

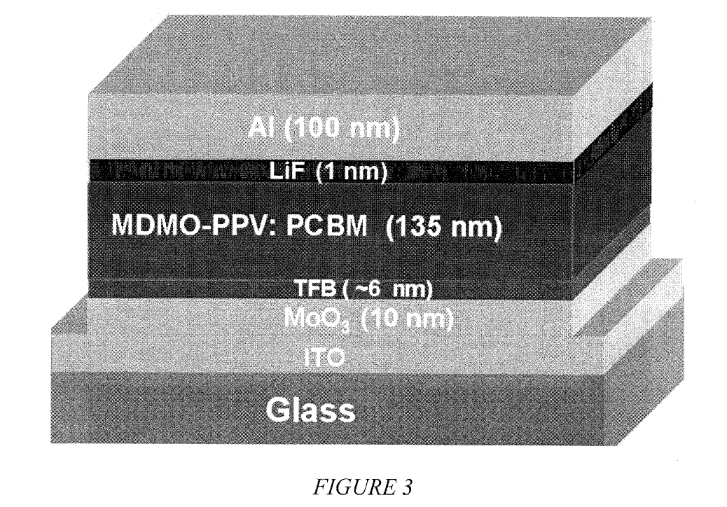

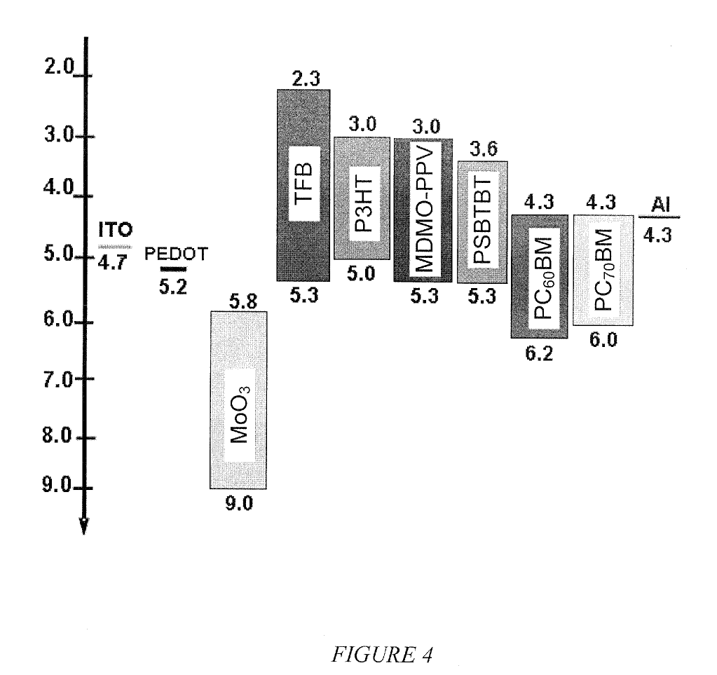

An exemplary PV cell, according to an embodiment of the invention, is that where a MoO₃/TFB double interlayer is employed with an bulk-heterojunction (BHJ) active layer comprising a poly(2-methoxy-5-(3,7-dimethyloctyloxy)-1,4-phenylene vinylene):[6,6]-phenyl-C61 butyric acid methyl ester (MDMO-PPV:PCBM) blend (see FIG. 1 for their structures), as illustrated in FIG. 3, which can be viewed with respect to the energy level diagram for these components and other possible components of a PV cell according to embodiments of the invention or state of the art cell without a double interlayer is shown in FIG. 4. An ITO coated glass comprises the anode and the aluminum cathode is used with a LiF cathode interlayer to couple the cathode to the BHJ active layer.

A PV device according to an exemplary embodiment of the invention, as illustrated in FIG. 3, can be constructed in the following manner. MoO₃ is deposited at a thickness of 5-50 nm, for example by PLD or other deposition methods, onto an ITO-coated transparent substrate to form the metal oxide layer of the anode double interlayer adjacent to the anode. Spin-coating a solution of TFB deposits a layer with a thickness of 2 to 10 nm onto the metal oxide layer to complete the form the novel anode double interlayer. TFB coating on top of the metal oxide layer enables chemical bonding between the polymer and the metal oxide surface, thus allowing further processing on top of the TFB layer. To deposit the photoactive layer on top of TFB, a solution comprising MDMO-PPV and PCBM, in any desired proportions, is spin-coated on the TFB layer to form a 10 to 200 nm BHJ active layer. Vapor-deposition of LiF at a thickness of 0.5 to 2 nm onto the BHJ active layer forms a cathode interlayer. Subsequently deposition of a metal, such as Al, forms a 20 to 200 nm thick cathode on the LiF layer. The device can then be encapsulated, for example by a UV-curable epoxy resin.

In other embodiments of the invention other cathodes, anodes, anode double interlayers, cathode interlayers, and BHJ active layers can be used in addition to those disclosed above. For example, the BHJ can comprise the electron-donating organic material poly(3-hexylthiophene) (P3HT), poly(2,7-(9-(2′-ethylhexyl)-9-hexyl-fluorene)-alt-5,5-(4′,7′-di-2-thienyl-2′,1′,3′-benzothiadiazole)) (PFDTBT), poly(2,6-(4,4-bis-(2-ethylhexyl)-4H-cyclopenta(2,1-b;3,4-6′)dithiophene)-alt-4,7-(2,1,3-benzothiadiazole)) (PCPDTBT), poly(p-phenylene-ethynylene)-alt-poly(p-phenylene-vinylene) (PPE-PPV), poly((2,7-(9-(2′-ethylhexyl)-9-hexyl-fluorene)-alt-5,5-(4′,7′-di-2-thienyl-2′,1′,3′-benzothiadiazole))-co-(2,7-(9-(2′-ethylhexyl)-9-hexyl-fluorene)-alt-2,5-thiophene))(APFO-5), poly(4,8-bis-alkyloxybenzo(1,2-b:4,5-b′)dithiophene-2,6-diyl-alt-(alkyl thieno(3,4-b)thiophene-2-(2-ethyl-1-hexanone)-2,6-diyl) (PBDTTT-C), poly(4,8-bis-alkyloxybenzo(1,2-b:4,5-b′)dithiophene-2,6-diyl-alt-(thieno(3,4-b)thiophene-2-carboxylate)-2,6-diyl) (PBDTTT-E), or poly[N-9′-heptadecanyl-2,7-carbazole-alt-5,5-(4′,7′-di-2-thienyl-2′,1′,3′-benzothiadiazole) (PCDTBT), aluminum phthalocyanine chloride (AlPcCl), or copper phthalocyanine (CuPc) with the electron-accepting organic material comprises a fullerene such as PCBM where the fullerene can be C₆₀ (see FIG. 1 for its structures) or C₇₀, ZnO nanoparticles, N-alkyl or N-aryl perylenediimides, perylenediimide containing polymers, CNPPV, TiO₂ or Cd/Pb-based nanoparticles.

The cathode can be, for example, calcium (Ca), aluminum (Al), Magnesium (Mg), titanium (Ti), tungsten (W), silver (Ag), gold (Au), other appropriate metals, or alloys of these metals. The cathode interlayer can be, for example, LiF, LiCoO₂, CsF, Cs₂CO₃, TiO₂, ZnO, or polyethylene oxide (PEO).

The transparent anode can be: other conductive metal oxides such as fluorine-doped tin oxide, aluminum-doped zinc oxide; a metal oxide metal laminate, such as ITO/Ag/ITO, Al doped ZnO/metal, or a thin metal layer where the metal layer can be, for example Ag, Au, Pd, Pt, Ti, V, Zn, Sn, Al, Co, Ni, Cu, or Cr; doped or undoped single walled carbon nanotubes (SWNTs); or patterned metal nanowires of gold, silver, or copper (Cu).

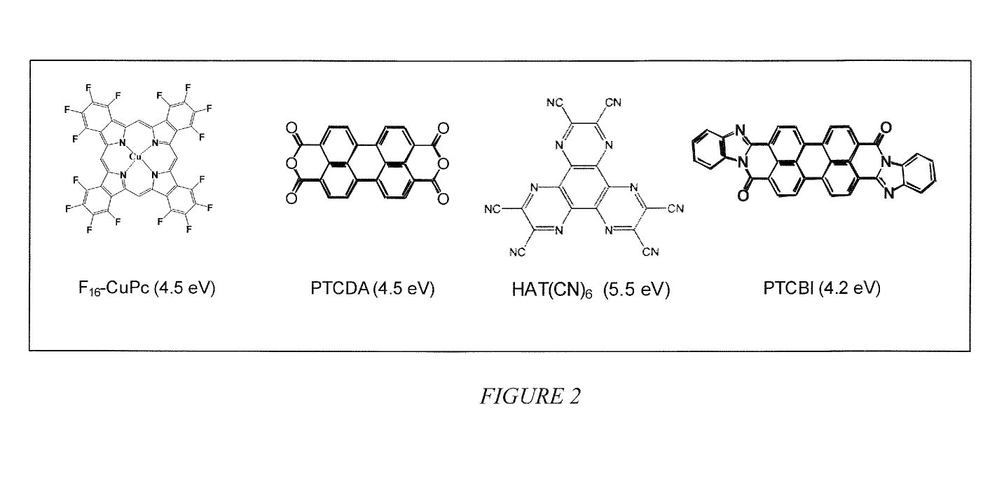

The metal oxide of the anode double interlayer can be, for example, V₂O₅, WO₃, NiO, or TiO₂. An alternate to the metal oxide can be an organic hole accepting transport material, for example, 1,4,5,8,9,12-hexaazatriphenylene-2,3,6,7,10,11-hexanitrile (HAT(CN)₆). In embodiments of the invention, the n-type semiconductor organic material is the interlayer between the anode and the hole transport layer and is selected from n-type organic compounds in addition to HAT(CN)₆ that include, but are not limited to: F₁₆-CuPc, 2,3,5,6-tetrafluoro-7,7,8,8-tetracyanoquinodimethane (F4TCNQ), 3,4,9,10-Perylenetetracarboxylic dianhydride (PTCDA), fluoro-substituted PTCDA, cyano-substituted PTCDA, naphthalene-tetracaboxylic-dianhydride (NTCDA), fluoro-substituted NTCDA, cyano-substituted NTCDA, and 3,4,9,10-perylene tetracarboxylic bisbenzimidazole (PTCBI) as illustrated in FIG. 2.

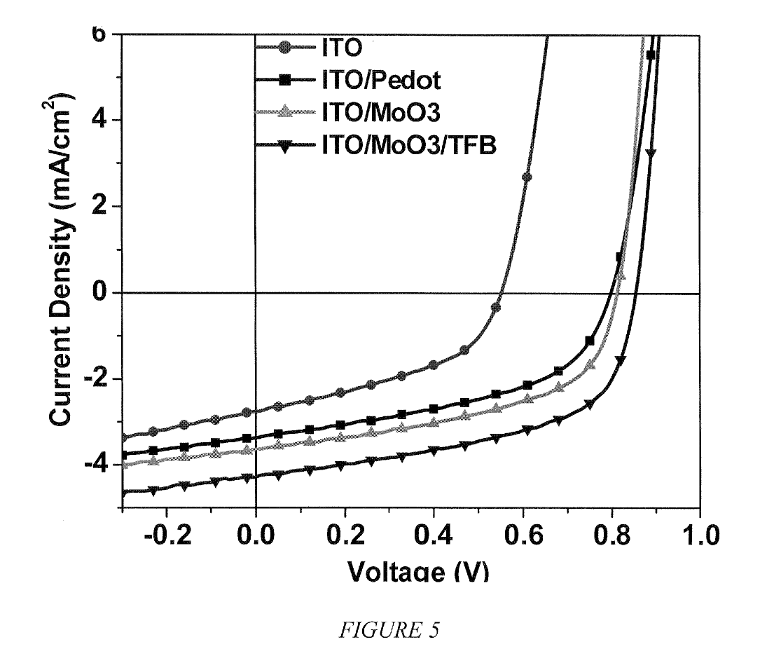

The hole accepting electron blocking material layer can be, for example, an aromatic amine having a plurality of nitrogen atoms such as 4,4′-bis[N-(p-tolyl)-N-phenyl-amino]biphenyl (TPD), 4,4′-bis[N-(1-naphthyl)-N-phenyl-amino]biphenyl (α-NPD), (4,4′-[bis-{(4-di-n-hexylamino)benzylideneamino)]stilbene (DRABS) and 4,4′-[bis-{(4-diphenylamino)benzylideneamino}]stilbene) (DPABS) or polymers, such as poly-N,N′-bis(4-butylphenyl)-N,N′-bis(phenyl)benzidine (poly-TPD), TFB and TFB analogues (see FIG. 1 for their structures). To illustrate the improved performance of PV cells according to embodiments of the invention, current density-voltage (J-V) characteristics were examined for PV devices with no interlayer and with different interlayers: MoO₃, PEDOT:PSS (see FIG. 1 for their structures) and MoO₃+TFB, as shown in FIG. 5. The device without an interlayer has low power conversion efficiency (PCE) of 0.67%, J_{sc} of 2.76 mA/cm², V_{oc} of 0.55V and FF of 0.44. Insertion of a PEDOT:PSS single layer between the ITO anode and the active layer improves the cell performance, displaying PCE, V_{oc}, J_{sc}, and FF of 1.31%, 3.37 mA/cm², 0.79 V and 0.48, respectively. Insertion of a MoO₃ single interlayer improves device performance to PCE=1.53%, J_{SC}=3.64 mA/cm², V_{OC}=0.81 V, and FF=0.52. Finally, inserting a MoO₃+TFB double interlayer between the ITO anode and the active layer gives a high device performance with V_{oc}=0.85 V, J_{sc}=4.28 mA/cm², and FF=0.55 where an increase of 53% in PCE to 2.01% is observed compared to that of the PEDOT:PSS cell. These parameters are compiled in Table 1, below for ease of comparison.

TABLE 1
Photovoltaic parameters of MDMO-PPV/PCBM
solar cell with various anode interlayer.

| Anode | J_{sc} | V_{oc} | FF | PCE | R_{S} |
|---|---|---|---|---|---|
| interlayer | (mA/cm²) | (V) | (%) | (%) | (Ω cm²) |
| Without | 2.76 | 0.55 | 44 | 0.67 | 34.05 |
| interlayer | | | | | |
| PEDOT | 3.37 | 0.79 | 48 | 1.31 | 32.76 |
| MoO₃ | 3.64 | 0.81 | 52 | 1.53 | 18.50 |
| MoO₃ + TFB | 4.28 | 0.85 | 55 | 2.01 | 16.20 |

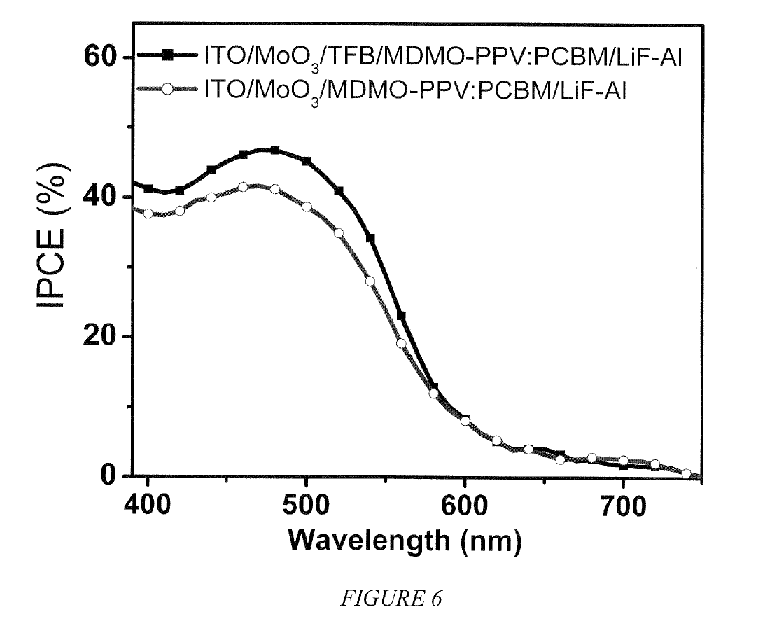

The enhancement of the device characteristics is attributed to the presence of the anode double interlayer that couples the efficient electron blocking properties of TFB with the enhanced charge extraction of MoO₃. FIG. 6 plots the incident photon-to-current conversion efficiency (IPCE) against wavelength for devices that differ only by the anode interlayer being a single layer MoO₃ or a double layer MoO₃+TFB. The IPCE of the MoO₃+TFB double interlayer cell is 47% verses 42% for the single MoO₃ interlayer cell.

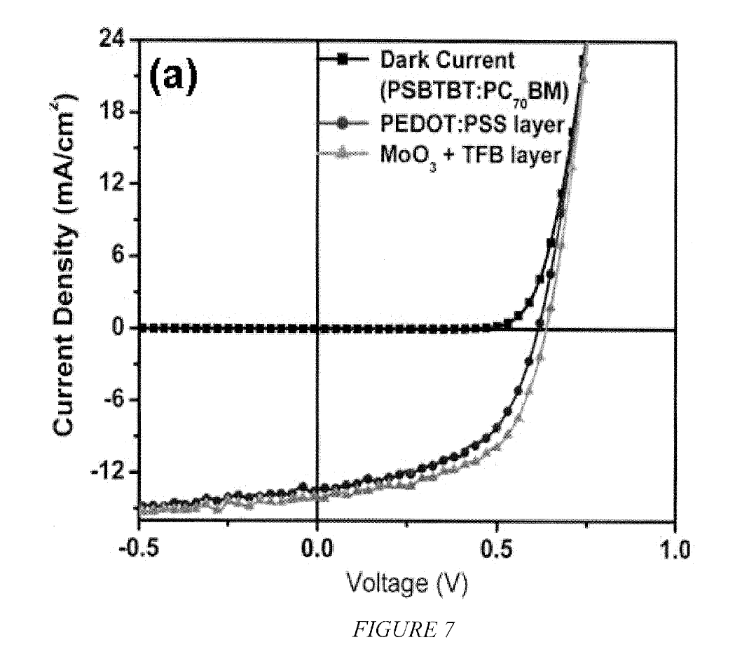

The double interlayer (MoO₃+TFB) strategy can be extended to PV devices with different BHJ active layers according to embodiments of the invention. The second exemplary embodiment of the invention is that of a PV cell using poly[(4,4′-bis(2-ethylhexyl)dithieno[3,2-b:2′,3′-d]silole)-2,6-diyl-alt-(2,1,3-benzothiadiazole)-4,7-diyl] (PSBTBT):PC₇₀BM (see FIG. 1 for a structure of the electron donating polymer) as the BHJ active layer. FIG. 7 shows J-V characteristics of PSBTBT polymer devices where a single interlayer of PEDOT:PSS is employed or the MoO₃+TFB double interlayer according to an embodiment of the invention is employed as the anode interlayer. Performances of these two devices are summarized in Table 2, below. This polymer PV cell with a PEDOT:PSS single interlayer shows a PCE of 4.27% while the PV cell with a MoO₃+TFB double interlayer shows a PCE of 4.91%.

TABLE 2
Photovoltaic parameters of PSBTBT/PC₇₀BM solar
cell with interlayer PEDOT: PSS and MoO₃ + TFB.

| | Jsc | Voc | FF | PCE |
|---|---|---|---|---|
| PV Device | (mA/cm²) | (V) | (%) | (%) |
| ITO/PEDOT: PSS/PSBTBT/ | 13.43 | 0.61 | 51 | 4.27 |
| PC₇₀BM/LiF/Al | | | | |
| ITO/MoO₃/TFB/PSBTBT/ | 14.00 | 0.63 | 56 | 4.91 |
| PC₇₀BM/LiF/Al | | | | |

A third exemplary device according to an embodiment of the invention that uses an anode double interlayer is PV device where the BHJ active layer comprises poly (3-hexylthiophene) (P3HT):PC₇₀BM (see FIG. 1 for structure of the electron donating polymer). Performances of the PV cells are summarized in Table 3, below. The device with double-interlayer (MoO₃+TFB) exhibits an enhanced performance of 25% compared to the device with PEDOT: PSS layer.

TABLE 3
Photovoltaic performance characteristics of P3HT/PC₇₀BM solar
cell with different interlayer (PEDOT: PSS and MoO₃ + TFB).

| | Jsc | Voc | FF | PCE |
|---|---|---|---|---|
| PV Device | (mA/cm²) | (V) | (%) | (%) |
| ITO/PEDOT: PSS/P3HT: | 9.50 | 0.57 | 59 | 3.18 |
| PC₇₀BM/LiF—Al | | | | |
| ITO/MoO3/TFB/P3HT: | 10.30 | 0.59 | 66 | 3.97 |
| PC₇₀BM/LiF—Al | | | | |

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

1. An organic PV cell comprising an anode having a double interlayer coupling a transparent electrode to a photoactive layer, wherein said double interlayer comprises a hole extracting layer and an organic hole transporting electron blocking material layer.

2. The organic PV cell of claim 1, wherein said hole extracting layer comprises a semiconducting metal oxide layer.

3. The organic PV cell of claim 2, wherein said metal oxide layer comprises MoO₃, V₂O₅, or WO₃.

4. The organic PV cell of claim 2, wherein said metal oxide layer comprises an n-type metal oxide semiconductor.

5. The organic PV cell of claim 1, wherein said hole extracting layer comprises an n-type organic semiconductor.

6. The organic PV cell of claim 5, wherein said n-type organic semiconductor is 1,4,5,8,9,12-hexaazatriphenylene-2,3,6,7,10,11-hexanitrile (HAT(CN)₆), fluoro-substituted CuPc, 2,3,5,6-tetrafluoro-7,7,8,8-tetracyanoquinodimethane (F4TCNQ), 3,4,9,10-Perylenetetracarboxylic dianhydride (PTCDA), fluoro-substituted PTCDA, cyano-substituted PTCDA, naphthalene-tetracaboxylic-dianhydride (NTCDA), fluoro-substituted NTCDA, cyano-substituted NTCDA, or 3,4,9,10-perylene tetracarboxylic bisbenzimidazole (PTCBI),

7. The organic PV cell of claim 1, wherein said organic hole accepting electron blocking material layer comprises an aromatic amine compound having a plurality of nitrogen atoms.

8. The organic PV cell of claim 7, wherein said aromatic amine compound comprises 4,4′-bis[N-(p-tolyl)-N-phenyl-amino]biphenyl (TPD), 4,4′-bis[N-(1-naphthyl)-N-phenyl-amino]biphenyl (α-NPD), (4,4′-[bis-{(4-di-n-hexylamino)benzylideneamino]stilbene (DHABS), 4,4′-[bis-{(4-diphenylamino)benzylideneamino}]stilbene) (DPABS), or combinations thereof.

9. The organic PV cell of claim 7, wherein said aromatic amine compound comprises a cross-linked aromatic amine resin.

10. The organic PV cell of claim 1, wherein said organic hole accepting electron blocking material layer comprises poly(9,9-dioctylfluorene-co-N-[4-(3-methylpropyl)]-diphenylamine) (TFB).

11. The organic PV cell of claim 1, wherein said organic hole transport electron blocking material layer comprises poly-N,N′-bis(4-butylphenyl)-N,N′-bis(phenyl)benzidine (poly-TPD).

12. The organic PV cell of claim 1, wherein said transparent anode comprises ITO.

13. The organic PV cell of claim 1, wherein said hole extracting layer comprises MoO₃.
